(19) United States
(12) Patent Application Publication
(10) Pub. No.: US 2014/0312474 A1
(43) Pub. Date: Oct. 23, 2014

(54) SEMICONDUCTOR PACKAGE WITH WIRE BONDING

(71) Applicant: TEXAS INSTRUMENTS INCORPORATED, Dallas, TX (US)

(72) Inventors: Alok Prakash Joshi, Maharastra (IN); Gireesh Rajendran, Kaggadasapura (IN); Brian Parks, Sherman, TX (US)

(73) Assignee: Texas Instruments Incorporated, Dallas, TX (US)

(21) Appl. No.: 13/866,200

(22) Filed: Apr. 19, 2013

(51) Int. Cl. H01L 23/00

(52) U.S. Cl. CPC H01L 24/49; H01L 24/43
USPC 257/666; 438/123

(57) ABSTRACT

A semiconductor package having a die having a plurality of electrically continuous die wire bonding sites includes a first die wire bonding site and a second die wire bonding site. The package includes a substrate having a plurality of electrically continuous substrate wire bonding sites including a first substrate wire bonding site and a second substrate wire bonding site. A first bondwire is connected between the first die wire bonding site and the first substrate wire bonding site and a second bondwire is connected between the second die wire bonding site and the second substrate wire bonding site. The first and second bondwires lie in adjacent, substantially parallel bondwire planes. The second bondwire is substantially skewed with respect to said first bondwire.

### BACKGROUND

Wire bonding is a method that has long been used for connecting the electrical components of integrated circuit packages. In a wire bond connection opposite ends of a thin bondwire are welded to conductive contact areas of two different components that are to be electrically connected. For mechanical reliability, thermal performance and ease of connection to printed circuit boards (PCB's), wire bond packages such as quad flat no lead packages (“QFN's”) and quad flat packages (“QFP's”) are preferred over wafer scale packages (“WSP”) and flip chip bail grid array packages (“FCBGA”). QFN and QFP packages, as opposed to WSP and FCBGA packages, have grounds and signal connections made using bondwires. The typical inductance of a single bondwire ground is on the order of 0.7 nH, as opposed to about 70 pH for a typical WSP ground connection.

However, there are problems associated with high parasitic inductance in bondwire packages. These problems include: efficiency degradation for power amplifiers (“PA”) and noise figure (“NF”); degradation for low noise amplifier (“LNA”): efficiency degradation for direct current to direct current (“DCDC”) convertors; high ripple levels for DCDC convertors; power supply reject ratio (“PSRR”) degradation for low drop out regulator (“LDO”); functionality issues such as instability for radio frequency (“RF”) blocks like PA's and LNA's; functionality issues like ringing and oscillations in intermediate frequency (“IF”) stages and LDO's; and reduced levels of isolation between various circuit blocks.

One conventional scheme to reduce parasitic inductance is to use multiple wires that are electrically connected in parallel, rather than a single wire, when connecting two electrical components, for example a die and leadframe. In doing this, typically wires of essentially identical size and shape are arranged in closely spaced, parallel planes. However a problem with this arrangement is that mutual coupling “k” caused by electrical current flow through closely adjacent wires counteracts the reduction of parasitic induction that would otherwise occur using multiple wires.

### BRIEF DESCRIPTION OF THE DRAWINGS

FIG. 1 is a top plan view of integrated circuit package.

FIG. 2 is a side elevation view of the integrated circuit package of FIG. 1.

FIG. 3 is a top plan view of a second embodiment of an integrated circuit package.

FIG. 4 is a side elevation view of the integrated circuit package of FIG. 3.

FIG. 5 is a flow chart of a method of electrically connecting a die to a substrate.

FIG. 6 is a diagram of projection areas used in defining certain terms used in the specification.

### DETAILED DESCRIPTION

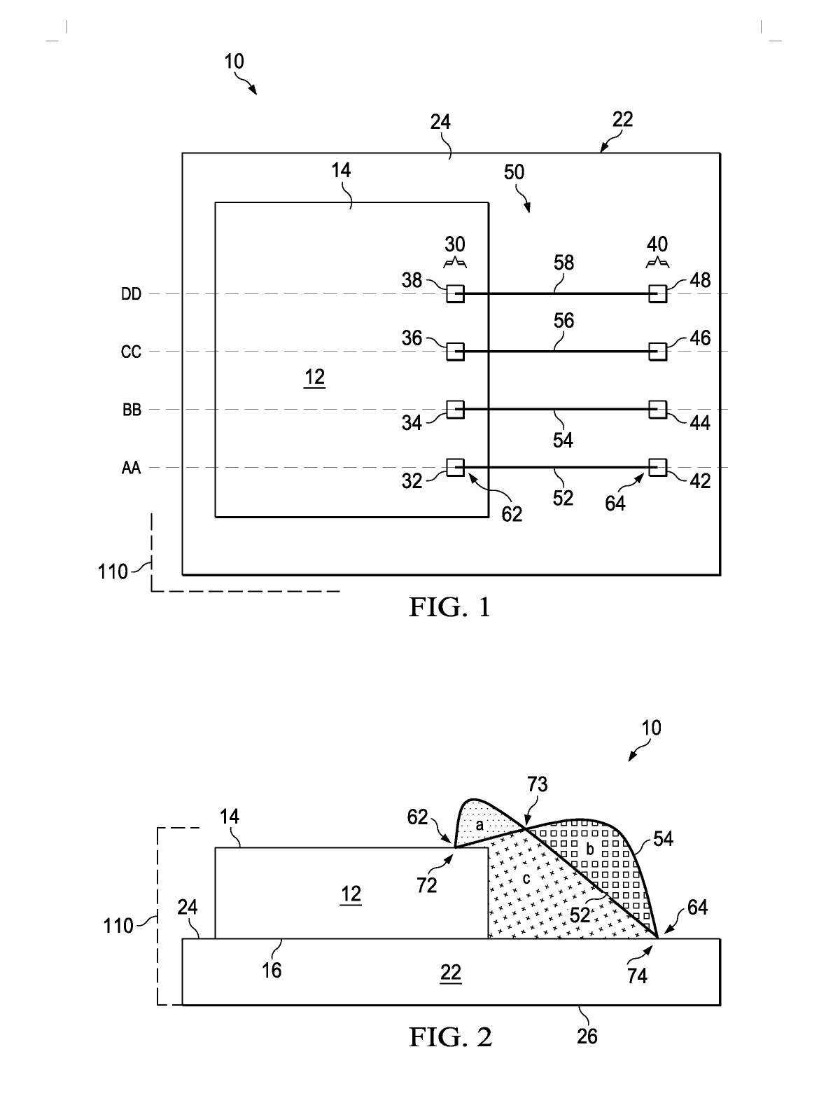

FIG. 1 is a top plan view of an integrated circuit package 10 having a die 12 and a substrate 22. The die 12 may be mounted on the substrate 22. The die 12 has a plurality of electrically continuous wire bonding sites 30, which may include a first site 32, a second site 34, a third site 36 and a fourth site 38. The wire bonding sites 30 may be conventional die contact pads that are in contact with a common conductor. in another embodiment the wire bonding sites 30 may be spaced apart sites on a conductive top surface portion of the die 12. In the embodiment illustrated in FIG. 1, the plurality of wire bonding sites 30 are positioned in a single row on a top surface 14 of the die 12.

In the integrated circuit package illustrated by FIGS. 1 and 2, the substrate 22 may have a plurality of electrically continuous (shorted together) wire bonding sites 40 which may include first 42, second 44, third 46 and fourth 48 wire bonding sites. In one embodiment, the substrate 22 is a lead frame and the wire bonding sites are spaced apart physical portions of the lead frame. The substrate 22 has a top surface 24 and an opposite bottom surface 26. The plurality of substrate wire bonding sites 40 may be provided on the top surface 24 of the substrate 22. In one embodiment, the bottom surface 16 of the die 12 is bonded to the top surface 24 of the substrate 22.

A plurality of bondwires 50, e.g., individual bondwires 52, 54, 56, 58, each have a first end 62 and a second end 64. The bondwires 50 may be connected between the plurality of electrically continuous wire bonding sites 30 on the die 12 and the plurality of electrically continuous wire bonding sites 40 on the substrate 22. The plurality of die wire bonding sites 30 and the plurality of substrate wire bonding sites 40 may be arranged such that the plurality of bondwires 50 are positioned in substantially parallel bondwire planes AA, BB, CC, and DD that extend substantially perpendicular to the top surface 14 of the die and the top surface 24 of the substrate 22. Although only four bondwires 50 are illustrated herein it will be understood that any number of bondwires arranged in parallel bondwires could be used.

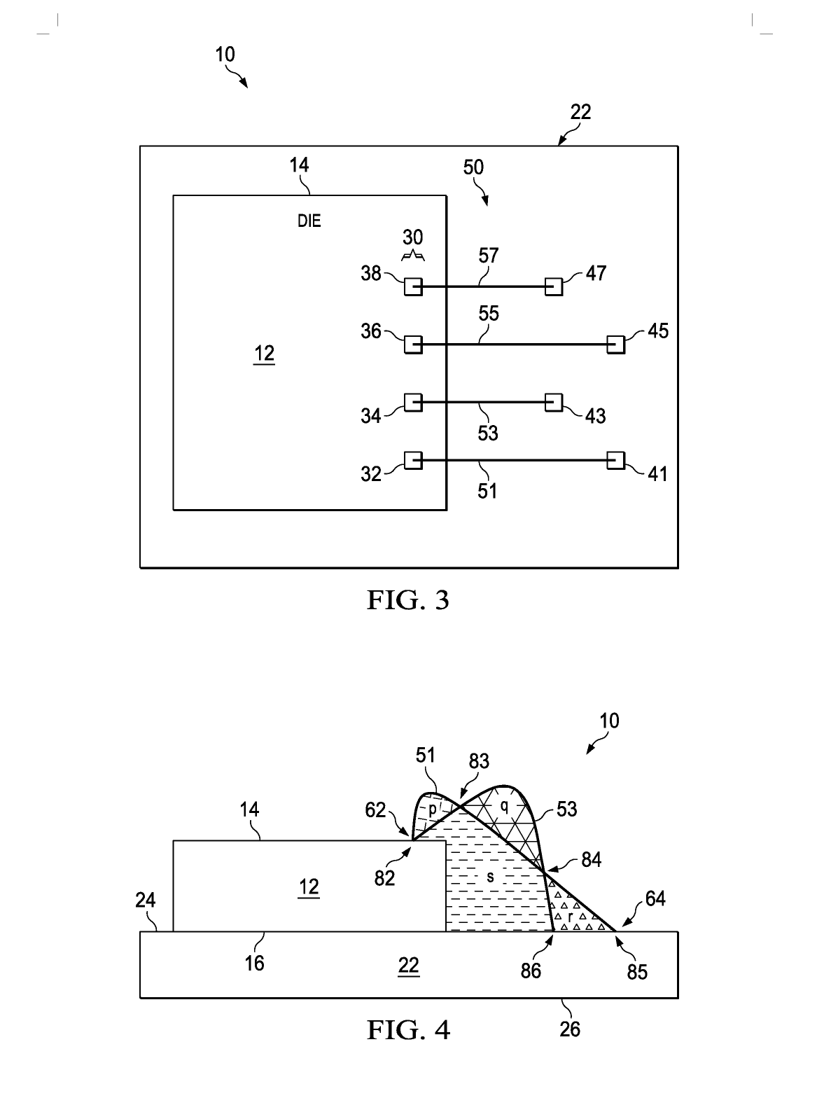

In the embodiment of FIGS. 3 and 4, the general construction of the die 10 and the substrate 22 may be identical to that illustrated in FIGS. 1 and 2, except that the substrate contact pads 41, 43, 45, 47 are staggered and positioned in two rows rather than a single row as in FIG. 1.

In the side elevation views of FIGS. 2 and 4, to avoid cluttering the drawing, only the first and second bondwires 52, 54 and 51, 53 are shown. In both the illustrated embodiments of FIGS. 1 and 2, and of FIGS. 3 and 4, the plurality of bondwires 50 have adjacent wires positioned in “substantially skewed” relationship, the second bondwire is substantially skewed with respect to the first bondwire, the third bondwire is substantially skewed with respect to the second bondwire and the fourth bondwire is substantially skewed with respect to the third bondwire, and vice versa.

The meaning of “substantially skewed” and other terms used in this specification will now be explained with reference to FIG. 6. The “projection area” of a bondwire 1 or 2 is the projection of the area subtended by a bondwire, e.g. bondwire 1, die 3 and substrate 4 onto a plane normal to the substrate (parallel to the planes of the bondwires). “Skew ratio” means complementary of the ratio of intersection of the area of projection of two bond wires 1, 2 by the union of the areas of projection of the two bondwires 1,2. In FIG. 6, although not expressly referenced on the drawing “A” is the projection area of the first bondwire, i.e., the area under wire 1 and above horizontal lines 3 and 4. “B” is the projection area of the second bondwire, i.e., the area under wire 2 and above horizontal lines 3 and 4. Skew ratio, “S”, may be defined mathematically as:

S=1−[(A intersection B)/(A union B)]

where (A intersection B)=(area with x's)
and where (A union B)=(area with x's)+(area with dots)+(area with squares)

FIG. 2, which is a view perpendicular to the bondwire planes AA, BB, CC, DD, illustrates that bondwires 52 and 54 have overlapping “projection profiles,” i.e., the projection of each wire onto a common projection plane parallel to the bondwire planes AA, BB, etc. These projection profiles and the top surfaces of the die 12 and substrate 22, in turn, define “profile enclosed areas” “a,” “b” and “c”. The first projection area “a” starts at a point 72 aligned with the bondwire attachment points 32, 34 and ends at a point 73 where the projections of the two wires 52, 54 overlap. The portions of the projection profiles of wires 52 and 54 between points 72 and 73 define enclosed area “a.” The projection profile enclosed area “b” extends from point 73 to a point 74 aligned with substrate bondwire contact sites 42 and 44 and is the area bounded by the portions of the projection profiles of wires 52 and 54 extending between points 73 and 74. The projection profile enclosed area “c” has an upper boundary defined by the lower of the two segments of the projection profiles of wires 52 and 54, i.e. the segment of the projection profile of wire 54 extending between points 72 and 73 and the segment of the projection profile of wire 52 extending between points 73 and 74. The lower boundary of enclosed area “c” is defined by horizontal lines associated with the top surface 14 of the die 12 and the top surface 24 of the substrate 22 that lie directly below the above described projection profile segments of wires 52 and 54. The term “skew ratio,” of adjacent bondwires, as used in this specification, in one case means the sum of the projection profile enclosed areas “a” and “b” divided by the sum of all the enclosed areas “a” and “b” and “c.” Thus, in a bondwire configuration such as illustrated in FIGS. 1 and 2, Skew Ratio=1−[(c/(a+b+c)]. In this situation, the first and second substrate wire bonding sites are aligned and thus represent a single point 74 in the side elevation view.

FIGS. 3 and 4 illustrate a situation in which adjacent bondwires, 51, 53, of the bondwires 51, 53, 55, 57 terminate at bondwire contact sites 41, 43 on the substrate 22, which are not aligned and which thus project as two different points 85, 86 when viewed from the side, i.e., in a direction perpendicular to the bondwire planes AA, BB, etc., as shown in FIG. 4 In this embodiment, the projection profiles of the two bondwires 51, 53 define four projection profile enclosed areas “p”, “q”, “r” and “s.” The two wires 51, 53 in the projection profile illustrated in FIG. 4, start at common point 82 associated with die contact pads 32, 34. The projection profiles of the wires 51, 53 again overlap at point 83 in FIG. 4. The projections of the two wires 51, 53 intersect a second time at point 84. Point 85 is aligned with second substrate wire bonding site 41 and point 86 is aligned with the substrate wire bonding site 43. Area “p” is defined by the projections of the two wires 51, 53 extending between points 82 and 83. Area “q” is the area between the projection of the wires 51 and 53 extending between projection points 83 and 84. Area “r” is the area defined by wire 51 extending between point 84 and 86 and wire 53 extending between point 84 and point 86 and the portion of the top surface 24 of the substrate 22 extending between points 85 and 86. Area “s” is defined by the portion of the projection of wire 53 between points 82 and 83, the projection of wire 51 between points 83 and 84, the projection of wire 53 between point 84 and 86 and lines defined by the top surfaces 14 and 24 of the die and substrate that lie below these wire projection portions. Thus, in the situation where one bondwire 51 terminates on the substrate at a different point than the second bondwire 53, the profile of the top surface 14 of the die 12 and the top surface 24 of the substrate 22 define portions of two of the profile enclosed areas, in this case area “r” and “s.” The other areas “p” and “q” are defined solely by the wire segments as in FIGS. 1 and 2. In the situation illustrated in FIGS. 3 and 4, the skew ratio is equal to the sum of the areas of “p,” “q” and “r” divided by the sum of all of the areas “p,” “q,” “r” and “s.” Thus for bondwires 51 and 53, SKEW RATIO=1−[s/(p+q+r+s)].

As the phrase “substantially skewed” is used in this specification, two adjacent bondwires in substantially parallel planes are substantially skewed if:
a) One bondwire is at least 20% longer than the other wire or
b) The skew ratio of the two bondwires is at least about 0.4 or
c) both a and b.

In some embodiment of the assemblies of FIGS. 1-4, the bondwires 50 first ends 62 are welded to the die 12 top surface 14 with bail bonds and the bondwires 50 second ends 64 are welded to the substrate 22 top surface 24 with stitch bonds. The diameters of the bondwires are typically in a range from about 20 μm about 30 μm. The bondwires 50 may be made from gold, copper, silver or aluminum. All of the bondwires 50 may have minimum lengths of about 0.7 mm. Adjacent bondwire planes, e.g., AA, BB etc., may be spaced apart from about 50 um to about 100 um.

The die 12 and portions of the substrate 22, which may be a leadframe, may be encapsulated in a protective layer 110 of encapsulant such as mold compound, as partially shown by dashed lines in FIGS. 1 and 2. in one embodiment the integrated circuit package 10, including the die 12, substrate 22 and the encapsulating layer 110, and possibly other electronic components (not shown) may be a quad flat no leads (“QFN”) package.

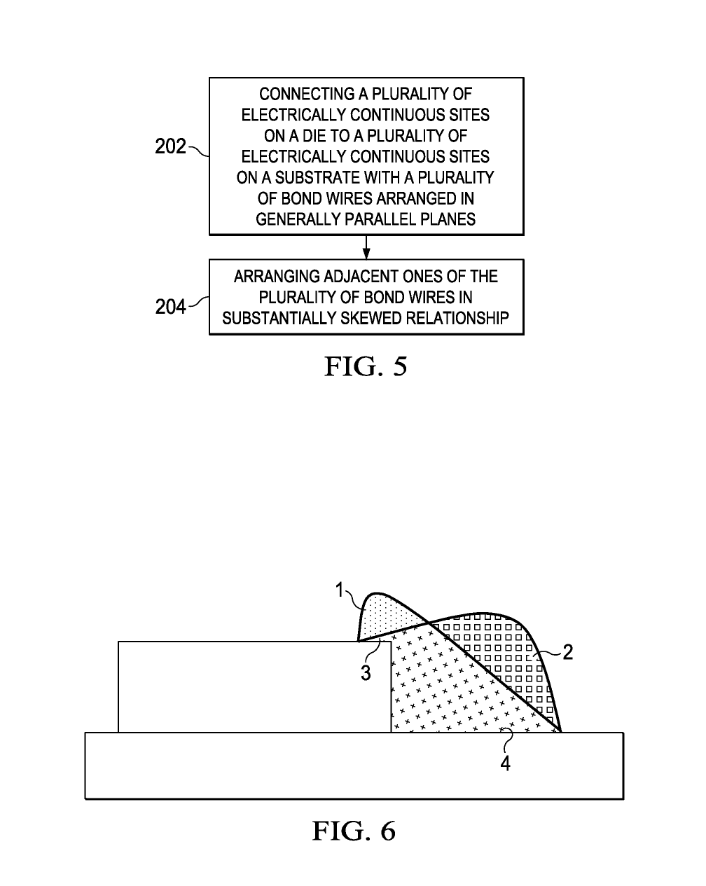

FIG. 5 illustrates a method of electrically connecting a die to a substrate. The method includes connecting a plurality of electrically continuous sites on a die to a plurality of electrically continuous sites on a substrate with a plurality of bondwires arranged in generally parallel planes, as shown at 202. The method also includes, as shown at 204, arranging adjacent ones of the plurality of bondwires in substantially skewed relationship.

While certain specific embodiments of a semiconductor package have been disclosed herein, the inventive concepts described in this specification may be otherwise embodied as will be apparent to those skilled in the art after reading this disclosure. The appended claims and their equivalents are intended to be broadly construed so as to cover such alternative embodiments, except to the extent limited by the prior art.

What is claimed is:

1. A semiconductor package comprising:
a die having a plurality of electrically continuous the wire bonding sites including a first die wire bonding site and a second die wire bonding site;
a substrate having a plurality of electrically continuous substrate wire bonding sites including a first substrate wire bonding site and a second substrate wire bonding site;
a first bondwire connected between first die wire bonding site and said first substrate wire bonding site;
a second bondwire connected between said second die wire bonding site and said second substrate wire bonding site, said first and second bondwires lying in adjacent, substantially parallel bondwire planes; and
wherein said second bondwire is substantially skewed with respect to said first bondwire.

2. The semiconductor package of claim 1 wherein said first bondwire is at least 20% longer than said second bondwire.

3. The semiconductor package of claim 2 wherein said first and second bondwires have a skew ratio of at least about 0.4.

4. The semiconductor package of claim 1 wherein said first and second bondwires have a skew ratio of at least about 0.4.

5. The semiconductor package of claim 1 wherein at least some of said plurality of electrically continuous wire bonding sites are arranged in staggered rows.

6. The semiconductor package of claim 1 wherein said die is mounted on said substrate.

7. The semiconductor package of claim 1 wherein said semiconductor package comprises a quad flat no lead package (“QFN”).

8. The semiconductor package of claim 1 wherein said substrate comprises a leadframe.

9. The semiconductor package of claim 1 wherein said adjacent, substantially parallel bondwire planes are spaced apart a distance of between about 50 um and 100 um.

10. A method of electrically connecting a the to a substrate comprising:
connecting a plurality of electrically continuous sites on a die to a plurality of electrically continuous sites on a substrate with a plurality of bondwires arranged in generally parallel planes; and
arranging adjacent ones of the plurality of bondwires in substantially skewed relationship.

11. The method of claim 10 wherein said arranging comprises making said second bondwire at least 20% shorter than said first bondwire.

12. The method of claim 10 wherein said arranging comprises arranging the first and second bondwires such that they have a skew ratio of at least 0.4.

13. The method of claim 10 wherein said connecting a plurality of electrically continuous sites on a die to a plurality of electrically continuous sites on a substrate with a plurality of bondwires comprises bail bonding first ends of the bondwires to the plurality of electrically continuous sites on the die.

14. The method of claim 10 wherein said connecting a plurality of electricaliy continuous sites on a die to a plurality of electrically continuous sites on a substrate with a plurality of bondwires comprises stich bonding second ends of the bondwires to the plurality of electrically continuous site on the substrate.

15. The method of claim 10 wherein said connecting a plurality of electrically continuous sites on a the to a plurality of electrically continuous sites on a substrate with a plurality of bondwires arranged in generally parallel planes comprises positioning adjacent ones of said plurality of bondwires between about 50 um and 100 um.

16. The method of claim 10 further comprising encapsulating the die, the plurality of bondwires and at least a portion of the substrate in mold compound to provide an integrated circuit package.

17. A quad flat no lead package (“QFN”) comprising:
a die having a plurality of electrically continuous the wire bonding sites including a first die wire bonding site and a second die wire bonding site;
a leadframe having a plurality of electrically continuous substrate wire bonding sites including a first substrate wire bonding site and a second substrate wire bonding;
a first bondwire connected between first die wire bonding site and said first substrate wire bonding site;
second bondwire connected between said second die wire bonding site and said second substrate wire bonding site, said first and second bondwires lying in adjacent, substantially parallel bondwire planes; wherein said second bondwire is substantially skewed with respect to said first bondwire; and
an encapsulating layer covering said bondwires and said the and at least a portion of said leadframe.

18. The QFN of claim 17 wherein said first bondwire is at least 20% longer than said second bondwire.

19. The QFN of claim 17 wherein said first and second bondwires have a skew ratio of at least about 0.4.

20. The QFN of claim 17 wherein said first and second bondwire planes are spaced apart between about 50 um and 100 um.
